(19) United States
(12) Patent Application Publication
(10) Pub. No.: US 2011/0143272 A1
(43) Pub. Date: Jun. 16, 2011

(54) IMAGE FORMING APPARATUS AND IMAGE STABILIZATION CONTROL METHOD USED IN IMAGE FORMING APPARATIS

(75) Inventors: Shingo Urasawa, Shizuoka (JP); Hirotaka Fukuyama, Shizuoka (JP)

(73) Assignees: KABUSHIKI KAISHA TOSHIBA, Tokyo (JP); TOSHIBA TEC KABUSHIKI KAISHA, Tokyo (JP)

(21) Appl. No.: 12/962,060

(22) Filed: Dec. 7, 2010

Related U.S. Application Data
(60) Provisional application No. 61/286,998, filed on Dec. 16, 2009.

(51) Int. Cl. G03F 7/20; G03G 15/01

(52) U.S. Cl. 430/30; 399/39

(57) ABSTRACT

According to an embodiment, an image forming apparatus includes an image holding member, a plurality of image forming units, an image density detection unit, an image density comparison unit, a control unit, a developer residual amount acquisition unit, and an image stabilization kind determination unit. The plurality of image forming units include at least a developer of a first color and a developer of a second color and form a predetermined pattern image on the image holding member using the developers of the first and second colors. The developer residual amount acquisition unit acquires a residual amount of the developer of the second color. The image stabilization kind determination unit switches control of an image to image stabilization control of forming the pattern image to be formed on the image holding member using only the developer of the first color if the residual amount of the developer of the second color acquired by the developer residual amount acquisition unit is below a threshold value defined in advance.

### CROSS-REFERENCE TO RELATED APPLICATION

This application is based upon and claims the benefit of priority from Provisional U.S. Application No. 61/286,998, filed on 16 Dec., 2009, the entire contents of which are incorporated herein by reference.

### FIELD

Embodiments described herein relate generally to an image forming apparatus and an image stabilization control method used in an image forming apparatus.

### BACKGROUND

In recent years, a demand for higher image quality in image forming apparatuses increases. In addition, the wide spread availability of color image forming apparatuses progresses. A color image forming apparatus develops a full color image on a target transfer body by sequentially overlapping toners of four colors, for example, Y (yellow), M (magenta), C (cyan), and K (black) on the target transfer body. Even with only a slight deviation in tone characteristics between the colors of the toners, image quality of a final image is changed. With regard to temporal changes and environmental changes in the image forming apparatus, it is important to maintain the tone characteristics at a constant level. Therefore, in order to maintain the tone characteristics constant all the time, various image stabilization control methods are being investigated.

In general, in an image stabilization control, a toner mark (pattern image) for testing, which is called a toner patch, is formed on an intermediate transfer belt that is an image holding member, or a sheet, and the image density thereof is detected by an optical sensor (toner adhesion amount sensor). In addition, on the basis of a detection signal from the optical sensor, the intensity or output timing of a developing bias or a drive signal for LEDs adapted to constitute an exposure apparatus is adjusted, and the image forming conditions for achieving a suitable density for a toner image of each color is adjusted. The image stabilization control is performed at a timing when the power of the image forming apparatus is turned on or when the cover thereof is opened and closed.

In addition, the color image forming apparatus has two printing modes including a color printing mode in which the toners of the all colors (YMCK) are used and a monochrome printing mode in which only the toner of the color black (K) is used. If the toner of any of the YMC colors is empty, only monochrome printing jobs may be continued.

However, in the image forming apparatus according to the related art, if any of the YMC colors is empty, since there are no color toners, the image stabilization control described above is not performed. Accordingly, the amount of the black toner adhered varies, and there may be cases where the amount of the toner consumed is not stable, resulting in a low image density.

### BRIEF DESCRIPTION OF THE DRAWINGS

FIG. 1 is a diagram schematically illustrating a configuration of an image forming apparatus according to an embodiment of the invention.

FIG. 2 is a diagram schematically illustrating a configuration of an image forming unit of the image forming apparatus illustrated in FIG. 1.

FIG. 3 is a block diagram illustrating a control system of the image forming apparatus illustrated in FIG. 1.

FIG. 4 is a flowchart illustrating a specific example of control of the image forming apparatus illustrated in FIG. 1.

FIG. 5 is a flowchart illustrating an image stabilization kind determination process of the image forming apparatus illustrated in FIG. 1 in detail.

FIG. 6 is a diagram illustrating an image stabilization control process of the image forming apparatus illustrated in FIG. 1 in detail.

FIG. 7 is a diagram illustrating an example of a tone pattern formed on an intermediate transfer belt 15 when color stabilization of the image forming apparatus illustrated in FIG. 1 is performed;

FIG. 8 is a diagram illustrating an example of a tone pattern formed on the intermediate transfer belt 15 when monochrome stabilization of the image forming apparatus illustrated in FIG. 1 is performed.

FIG. 9 is a conceptual diagram of tone correction performed by the image forming apparatus illustrated in FIG. 1.

### DETAILED DESCRIPTION

According to an embodiment of the invention, an image forming apparatus includes an image holding member, a plurality of image forming units, an image density detection unit, an image density comparison unit, a control unit, a developer residual amount acquisition unit, and an image stabilization kind determination unit.

The plurality of image forming units include at least a developer of a first color and a developer of a second color and form a predetermined pattern image on the image holding member using the developers of the first and second colors. The image density detection unit detects the image density of the pattern image formed on the image holding member. The image density comparison unit compares the image density of the pattern image detected by the image density detection unit to a target density. The control unit changes the image forming conditions used by the plurality of image forming units on the basis of the comparison result of the image density comparison unit. The developer residual amount acquisition unit acquires the residual amount of the developer of the second color. The image stabilization kind determination unit switches control of an image to image stabilization control of forming the pattern image to be formed on the image holding member using only the developer of the first color if the residual amount of the developer of the second color acquired by the developer residual amount acquisition unit is below a threshold value defined in advance.

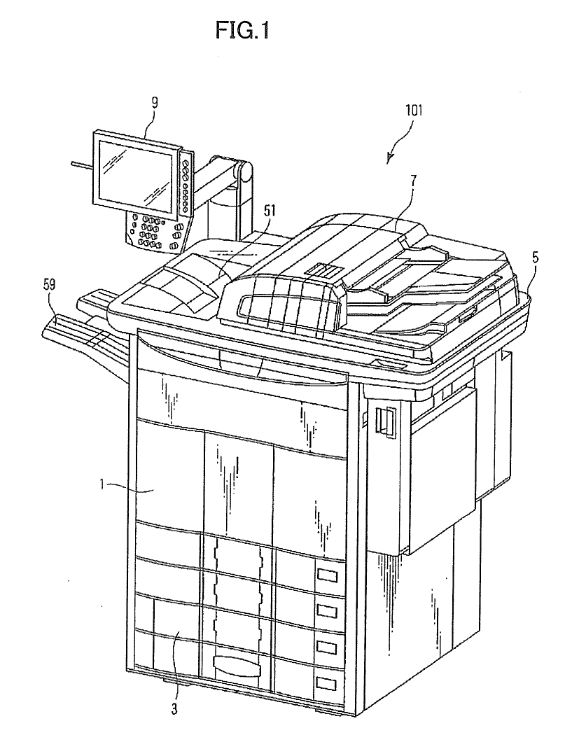

FIG. 1 is a perspective view illustrating an outer appearance of an image forming apparatus 101 according to an embodiment of the invention. The image forming apparatus 101 is a quadruple tandem-type color copying machine. The image forming apparatus 101 includes, for example, an image forming unit 1 for outputting image information as an output image that is called a hard copy or a printout, a sheet feeding unit 3 for feeding sheets (output media) of arbitrary sizes to be used by the image forming unit 1 for outputting images, and a scanner (image reading unit) 5 for scanning image information which is a target for forming images in the image forming unit 1 from a target object (hereinafter, called an original document) as image data. In addition, an automatic document feeding apparatus 7 is provided on the image forming unit 1. If the original document has a sheet type, the automatic document feeding apparatus 7, after the image reading unit 5 terminates reading the image information, discharges the original document, which is read, from a reading position to a discharge position, and guides a next original document to the reading position. In addition, in the image forming apparatus 101, a display unit 9 which is an instruction input unit for instructing the image forming unit 1 to start image formation and instructing the image reading unit 5 to start reading image information on original documents, that is, a control panel is provided.

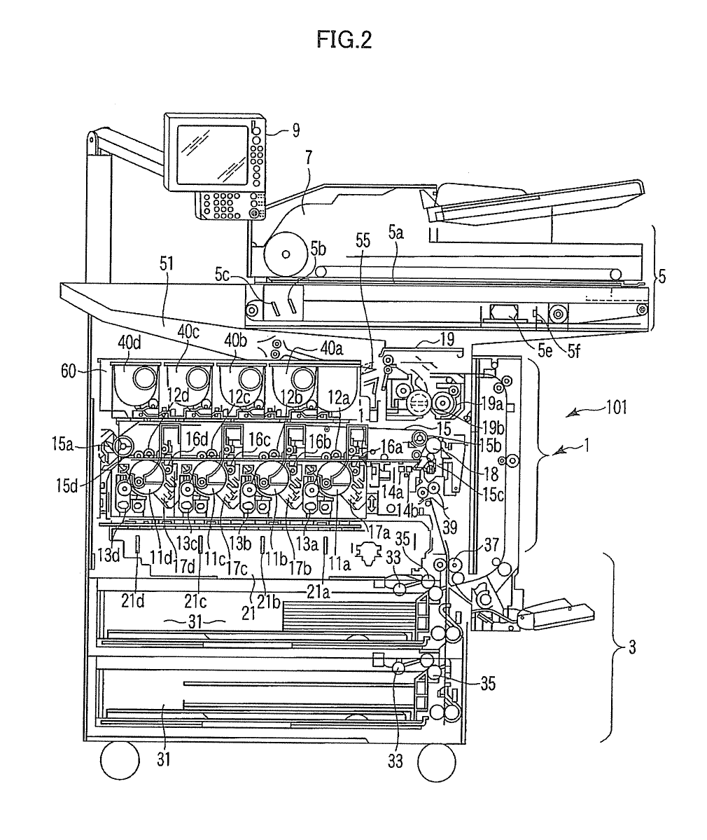

FIG. 2 is a diagram schematically illustrating an internal structure of the image forming apparatus 101 in front view. First, a structure of the image reading unit 5 is described. The image reading unit 5 includes a transparent platen glass 5a on which an original document is placed, a light source 5b for illuminating the original document, and a reflective mirror 5c for reflecting light reflected from the original document. In addition, the light source 5b and the reflective mirror 5c are formed integrally with a document illumination unit 5d which is movable in a horizontal direction. The light reflected by the document illumination unit 5d is received via an imaging lens 5e disposed on a light path.

Next, a configuration of the image forming unit 1 is described. On an upper side of the image forming unit 1, toner cartridges 40a, 40b, 40c, and 40d are arranged in parallel. The toner cartridges 40a, 40b, 40c, and 40d are attachable to and detachable from a cartridge holding mechanism 60 provided on a front surface side of the image forming unit 1. The toner cartridges 40a, 40b, 40c, and 40d supply toners of yellow (Y), magenta (N), cyan (C), and black (K). In addition, in the vicinities of the toner cartridges 40a, 40b, 40c, and 40d, toner sensors 70a, 70b, 70c, and 70d (not shown) are respectively provided to sense the amount of residual toners of the corresponding colors.

The image forming unit 1 includes first to fourth photoconductive drums 11a to 11d as image holding members for holding latent images, developing apparatuses 13a to 13d for developing the latent images formed on the photoconductive drums 11a to 11d, an intermediate transfer belt 15 for holding images of developers developed on the photoconductive drums 11a to 11d in an overlapping state, cleaners 16a to 16d for respectively removing the toners remaining on the photoconductive drums 11a to 11d from the photoconductive drums 11a to 11d, and chargers 17a to 17d for identically charging the photoconductive drums 11a to 11d.

In addition, the image forming unit 1 includes a transfer apparatus 18 for transferring the images of the developers overlapping on the intermediate transfer belt 15 onto an output medium in a sheet type such as a general sheet of paper which is not subjected to specific processing, or an OHP sheet which is a transparent resin sheet, and a fixing apparatus 19 for fixing the images of the developers transferred onto the transferred medium to the output medium. In addition, the image forming unit 1 includes an exposure apparatus 21 having LEDs 21a to 21d for forming latent images by allowing laser light modulated according to image data for writing to illuminate the photoconductive drums 11a to 11d.

The intermediate transfer belt 15 is stretched by a driving roll 15a for rotating the intermediate transfer belt 15, a tension roll 15b for maintaining a constant tensile force applied to the intermediate transfer belt 15, and a backup roll 15c for secondary transfer.

At points (primary transfer portions) where the intermediate transfer belt 15 comes in contact with the photoconductive drums 11a to 11d, on a rear surface side of the intermediate transfer belt 15, primary transfer rolls 12a to 12d are disposed which come in pressing contact with the photoconductive drums 11a to 11d via the intermediate transfer belt 15.

The transfer apparatus 18 is disposed to come in contact with the intermediate transfer belt 15 (secondary transfer portion) on a toner holding surface side (outer side) of the intermediate transfer belt 15, and opposes to the backup roll 15c disposed on the rear surface side (inner side) of the intermediate transfer belt 15.

In addition, at a point where the driving roll 15a is provided on the intermediate transfer belt 15, a belt cleaner 15d is disposed to come in contact with the intermediate transfer belt 15 at a position opposing the driving roll 15a while nipping the intermediate transfer belt 15.

In addition, an LED light source 14a and an optical sensor 14b for detecting the amount of reflected light of the toner pattern formed on the intermediate transfer belt 15 are disposed between a fourth station of the primary transfer portions and the second transfer portion.

The first to fourth photoconductive drums 11a to 11d respectively hold electrostatic images (latent images) to be visualized (developed) by the developing apparatuses 13a to 13d which accommodate the toners of the arbitrary colors including yellow (Y), magenta (M), cyan (C), and black (K). However, the arrangement order is prescribed as a predetermined order according to an image forming process and characteristics of the toners (developers). The intermediate transfer belt 15 holds the developer images of the colors formed by the first to fourth photoconductive drums 11a to 11d and the corresponding developing apparatuses 13a to 13d in the formation order.

The sheet feeding unit 3 feeds the output medium to the transfer apparatus 18 at a predetermined timing when the images of the developers are transferred by the transferring apparatus 18.

Cassettes set by a plurality of cassette slots 31 accommodate output media with arbitrary sizes. In response to an image forming operation, a pickup roller 33 picks up the output medium. The size of the output medium corresponds to the size of the image of the developer formed by the image forming unit 1. A separation mechanism 35 prevents the pickup roller 33 from picking up two or more output media from the cassette. A plurality of carrying rollers 37 carries the output medium limited to one sheet by the separation mechanism 35 toward an aligning roller 39. The aligning roller 39 sends the output medium to a transfer position at which the transfer apparatus 18 and the intermediate transfer belt 15 come in contact with each other in synchronization with a timing at which the transfer apparatus 18 transfers the images of the developers from the intermediate transfer belt 15. Moreover, cassette slots 31, the pickup roller 33, and the separation mechanism 35 may be prepared to be plural in number as needed, and the cassette is arbitrarily attachable to a different slot.

The output medium on which the image information is fixed by the fixing apparatus 19 is discharged to a paper discharge tray 51 defined on the image forming unit 1 on a lateral side of the image reading unit 5. Here, the fixing apparatus 19 has a fixing roller 19a and a pressurizing roller 19b on the downstream side of the discharge direction. The image information is fixed to the output medium on which the images of the developers are transferred as the images of the developers are fused by the fixing roller 19a and the pressurizing roller 19b which are heated to 180° C.

In addition, the image forming apparatus 101 has a lateral paper discharge tray 59 on a side surface of the image forming unit 1. The output medium discharged from the fixing apparatus 19 is guided to the lateral paper discharge tray 59 via an interruption carrying unit 71 connected to a switching unit 55.

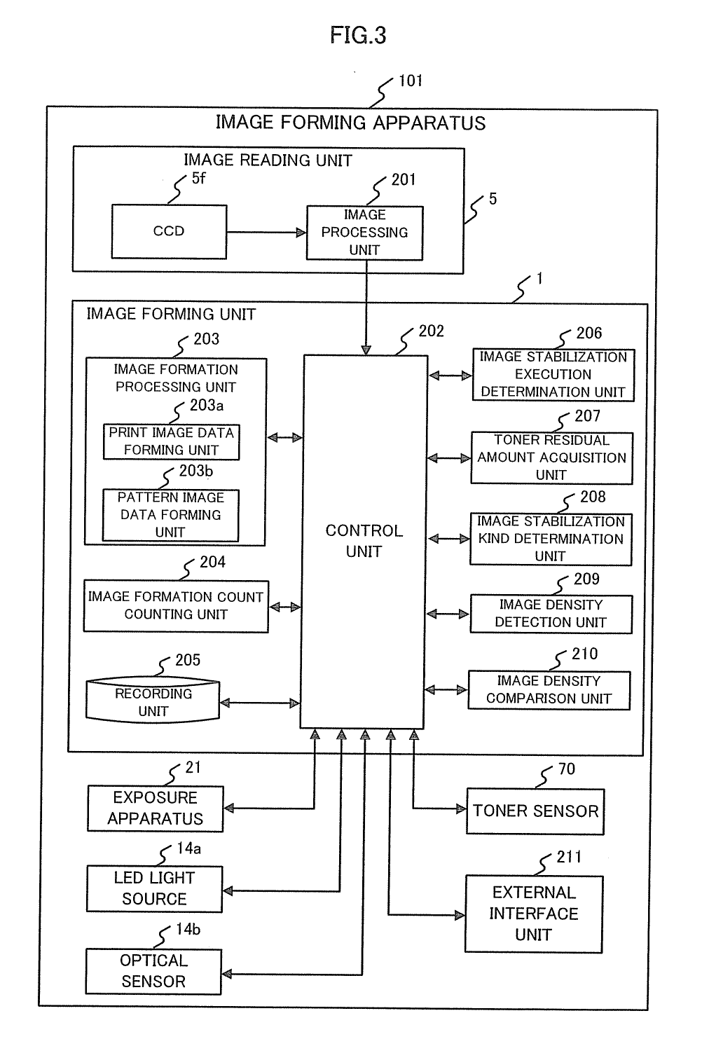

FIG. 3 is a block diagram illustrating a control system of the image forming apparatus 101 according to the embodiment. An image processing unit 201 is provided on the image reading unit 5 side. The image processing unit 201 converts an output signal from reflected light received by a CCD 5f into image data of yellow (Y), magenta (M), cyan (C), and black (K) and performs data processing such as density correction thereon to be output as image data for writing.

In addition, the image forming unit 1 includes a control unit 202, an image formation processing unit 203, an image formation count counting unit 204, a recording unit 205, an image stabilization execution determination unit 206, a developer residual amount acquisition unit 207, an image stabilization kind determination unit 208, an image density detection unit 209, and an image density comparison unit 210.

The control unit 202 controls LEDs 21a to 21d of the exposure apparatus 21 for allowing laser light modulated according to the image data for writing of the image processing unit 201 to illuminate the photoconductive drums 11a to 11d. In addition, the control unit 202 switches an image forming job for a color image to an image forming job for a monochrome image on the basis of a processing result of the image stabilization kind determination unit 208. In this case, until a comparison result of the image density comparison unit 210 described later is harmonized, while the pattern image density is adjusted, a pattern image for monochrome stabilization of the image formation processing unit 203 is repeatedly formed on the intermediate transfer belt 15. For example, when color image formation counts reach a predetermined threshold value, immediately after the power of the image forming apparatus 101 is in the ON state, or, if it is determined that re-adjustment of tone characteristics is needed according to a condition determined in advance such as after a predetermined lapse of time, the control unit 202 performs image stabilization control processing.

The image formation processing unit 203 forms the images (color images/monochrome images) of the developers transferred on the intermediate transfer belt 15 and outputs them to the exposure apparatus 21.

The image formation count counting unit 204 counts image formation counts of the image formation processing unit 203 and records the counted counts in the recording unit 205.

The recording unit 205 records the image formation counts and an image formation count upper limit which is an execution determination reference of the image stabilization control for each kind (color image/monochrome image) of the images formed by the image formation processing unit 203. If the image stabilization control is regularly performed, it is preferable that the image formation count upper limit of the color image be set to, for example, 500 counts.

The image stabilization execution determination unit 206 determines whether or not execution of the image stabilization control is needed by comparing the image formation counts corresponding to the image kind to the image formation count upper limit.

The developer residual amount acquisition unit 207 acquires a developer residual amount for each color in the developing apparatuses from the toner sensors 70. If the image stabilization execution determination unit 206 determines that execution of the image stabilization control is needed and the residual amount of the color developer (color toner) acquired by the developer residual amount acquisition unit 207 is below the threshold defined in advance, the image stabilization kind determination unit 208 accepts only the image forming job for the monochrome image while not accepting the image forming job for the color image thereafter.

The image density detection unit 209 calculates the image density of the pattern image formed on the intermediate transfer belt 15 during the execution of the image stabilization control. In addition, the image density detection unit 209 receives the reflected light of the light illuminated on the pattern image on the intermediate transfer belt 15 by the LED light source 14a through the optical sensor 14b, and calculates the pattern image density from the reflectance.

The image density comparison unit 210 compares the pattern image density calculated by the image density detection unit 209 to a predetermined target density and outputs the comparison result to the control unit 202.

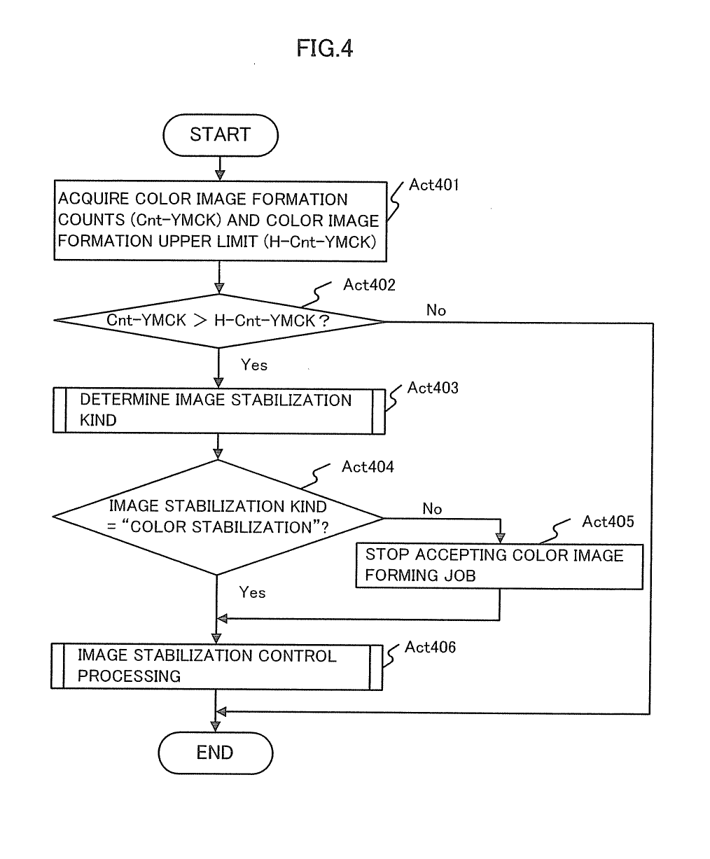

Next, a control operation of the image forming apparatus according to the embodiment will be described with reference to the flow chart illustrated in FIG. 4.

In Act 401, the image stabilization execution determination unit 206 acquires the color image formation counts (Cnt-YMCK) and the color image formation upper limit (H-Cnt-YMCK) from the recording unit 205.

In Act 402, the image stabilization execution determination unit 206 determines whether or not the color image formation counts (Cnt-YMCK) exceeds the color image formation upper limit (H-Cnt-YMCK). Here, the image stabilization execution determination unit 206 proceeds to Act 403 if it is determined that the color image formation counts (Cnt-YMCK) exceeds the color image formation upper limit (H-Cnt-YMCK) (Yes in Act 402). Contrary to this, if it is determined that the color image formation counts (Cnt-YMCK) are equal to or smaller than the color image formation upper limit (H-Cnt-YMCK) (No in Act 402), the image stabilization execution determination unit 206 terminates the processing.

In Act 403, the image stabilization kind determination unit 208 performs image stabilization kind determination processing described later and outputs the determined stabilization kind to the control unit 202.

In Act 404, the control unit 202 determines whether or not the image stabilization kind output from the image stabilization kind determination unit 208 is “color stabilization”. Here, if it is determined that the image stabilization kind is “color stabilization” (Yes in Act 404), the control unit 202 proceeds to Act 406. Contrary to this, if it is determined that the image stabilization kind is “monochrome stabilization” (No in Act 404), the control unit 202 proceeds to Act 405.

In Act 405, the image stabilization kind determination unit 208 then outputs a processing result where the image forming job for the color image is not accepted and only the image forming job for the monochrome image is accepted, to the control unit 202.

In Act 406, the control unit 202 causes the image formation processing unit 203 to execute the image stabilization control processing of the kind determined in Act 403.

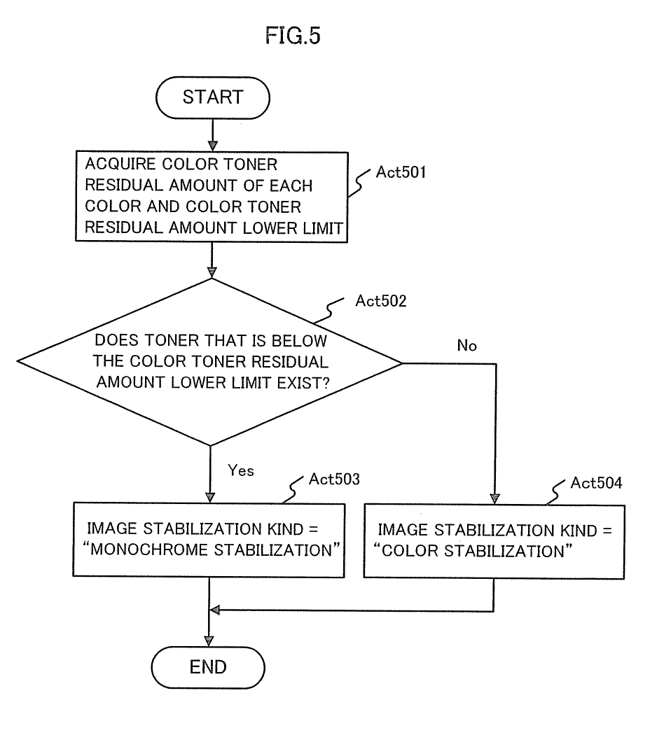

Next, the image stabilization kind determination processing illustrated in Act 403 of FIG. 4 will be described in detail with reference to a flowchart of FIG. 5.

In Act 501, the image stabilization kind determination unit 208 acquires the residual amount of the color developer (color toner) of each color in the developing apparatuses via the developer residual amount acquisition unit 207 and acquires a color toner residual amount lower limit for each color from the recording unit 205.

In Act 502, the image stabilization kind determination unit 208 determines whether or not there is toner which is below the color toner residual amount lower limit. Here, the image stabilization kind determination unit 208 proceeds to Act 503 if it is determined that toner of which the color toner residual amount is below the color toner residual amount lower limit exists (Yes in Act 502). Contrary to this, the image stabilization kind determination unit 208 proceeds to Act 504 if it is determined that there is no toner for which the color toner residual amount is below the color toner residual amount lower limit not exist (No in Act 502).

In Act 503, the image stabilization kind determination unit 208 outputs a result that the image stabilization kind is “monochrome stabilization” to the control unit 202, and the processing is terminated.

In Act 504, a result that the image stabilization kind is “color stabilization” is output to the control unit 202, and the processing is terminated.

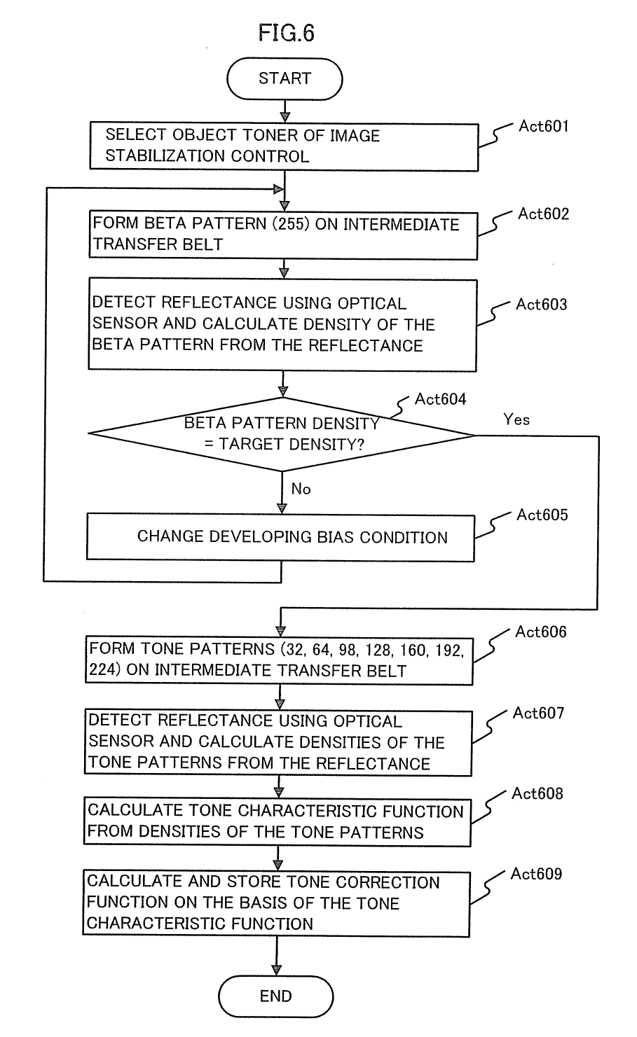

Next, the image stabilization control processing illustrated in Act 406 of FIG. 4 will be described in detail with reference to a flowchart of FIG. 6.

In Act 601, the control unit 202 selects a toner which is an object of the image stabilization control on the basis of the image stabilization kind output from the image stabilization kind determination unit 208.

In Act 602, the control unit 202 controls the image formation processing unit 203, and forms a beta pattern image having a tone density of, for example, 255/255 in a halftone screen of 160 lines on the intermediate transfer belt 15. The control unit 202 supplies the beta pattern image generated by the image formation processing unit 203 to the exposure apparatus 21. In addition, the exposure apparatus 21 forms latent images of the beta pattern image on the photoconductive drums 11a to 11d. On the other hand, the developing apparatuses 13a to 13d develop the latent images. The developed images are formed on the surface of the photoconductive drums 11a to 11d. Then, the developed images are transferred onto the intermediate transfer belt 15.

In Act 603, the image density detection unit 209 acquires the reflectance of the beta pattern transferred onto the intermediate transfer belt 15 from the optical sensor 14b, and calculates the density of the beta pattern (hereinafter, referred to as a beta pattern density) from the reflectance.

In Act 604, the image density comparison unit 209 determines whether or not the beta pattern density reaches a target density. Here, if it is determined that the beta pattern density is not reached (No in Act 604), the image density comparison unit 209 detects an error from the target value set in advance and outputs the error to the control unit 202, the control unit 202 changes the image forming conditions on the basis of the output error (Act 605), and processing of Acts 602 to 604 is repeated until it is determined that the beta pattern density is the same as the target density (Yes in Act 604).

The changing of the image forming conditions to the target density in Act 605 can be implemented through maintaining a developing bias value applied between the developing apparatuses 13a to 13d and the photoconductive drums 11a to 11d and a charging potential of the photoconductive drums 11a to 11d charged by the chargers 17a to 17d at the same potential difference and adjusting the beta pattern density by changing the developing contrast potential by the control unit 202. In a method of adjusting the beta pattern density according to an error between the image density of the beta pattern and the target density of the beta pattern density, the control unit 202 may apply correction amounts of the developing bias value and the charging bias value recorded as a table in advance on the recording unit 205. The control unit 202 prints the beta pattern again or a high-density pattern, senses the beta pattern density after correcting the developing bias value and the charging bias value, receives the result, and executes the same correction control again.

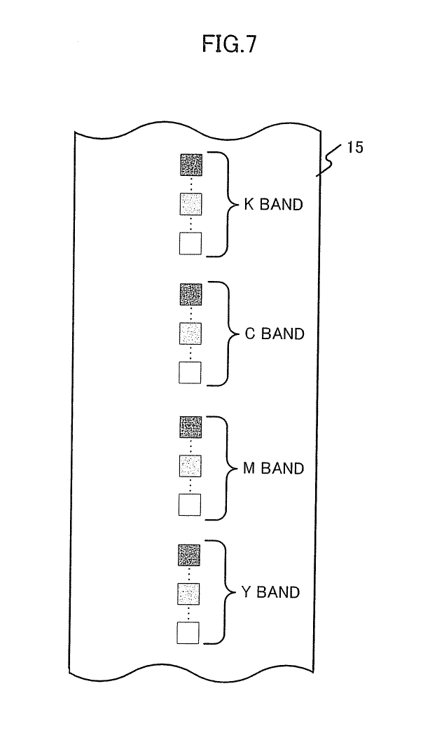

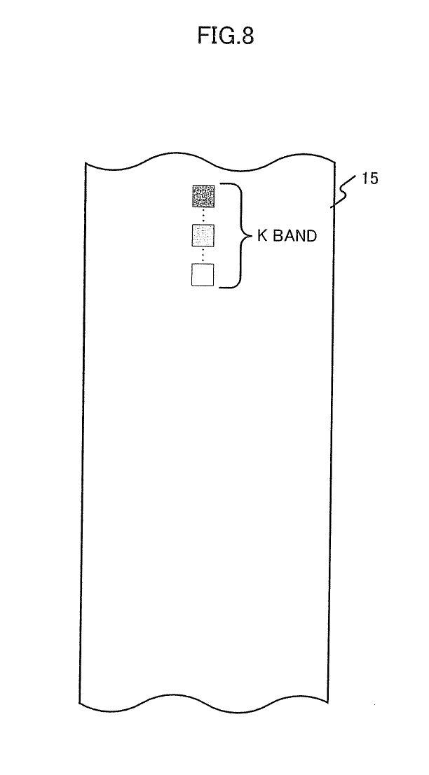

In Act 606, the control unit 202, in a state where the beta pattern density becomes the target density value, controls the image formation processing unit 203 to form a tone pattern in a halftone as a tone screen pattern on the intermediate transfer belt 15. The control unit 202 reads 7 patterns (hereinafter, referred to as tone patterns), for example, according to tone levels including 32/255, 64/255, 96/255, 128/255, 160/255, 192/255, and 224/255 depending on halftone screens of 160 lines from the recording unit 205, and forms the patterns on the intermediate transfer belt 15. FIG. 7 illustrates an example of the tone pattern formed on the intermediate transfer belt 15 during the color stabilization. Here, a band of 16 tone pattern patches of each of yellow (Y), magenta (M), cyan (C), and black (K) is formed on the intermediate transfer belt 15. FIG. 8 illustrates an example of a tone pattern formed on the intermediate transfer belt 15 during the monochrome stabilization. Here, a band of the 16 tone pattern patches of only the black (K) is formed on the intermediate transfer belt 15.

In Act 607, the image density detection unit 209 detects the reflectance of the tone pattern such as atone level using the optical sensor 14b and obtains the tone pattern density from the reflectance detected by the optical sensor 14b.

In Act 608, the control unit 202 obtains a tone characteristic table of the halftone screens of the 160 lines or a tone characteristic function on the basis of the tone pattern density calculated by the image density detection unit 209. Furthermore, the relationship in tone value between the reflectance detected by the optical sensor 14b and the final image for the output medium may be recorded on the recording unit 205 in advance.

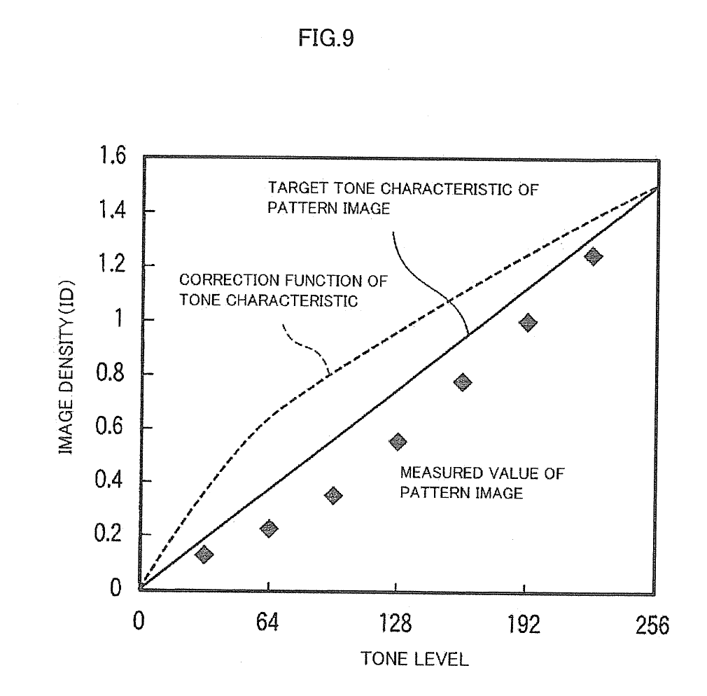

In Act 609, the control unit 202 calculates a tone correction table or a tone correction function for correcting the error of the tone (that is typically linear with respect to an input) set in advance from the tone characteristic table or the tone characteristic function. In addition, the control unit 202 records the obtained tone correction table or the tone correction function by calculating the recording unit 205 and terminates the processing. Here, FIG. 9 is a conceptual view of the tone correction described above. The horizontal axis represents tone level, and the vertical axis represents image density. The vertical axis may be value standardized according to a so-called image density value 1.5.

As such, in the image forming apparatus according to this embodiment, the configuration in which even if the color toner becomes empty and color printing is switched to monochrome printing, the monochrome stabilization is performed before the monochrome printing is performed is employed. Therefore, variations in the amount of black toner adhered can be avoided, and the monochrome printing can be stably performed.

Furthermore, the image stabilization control of the above-described embodiment is implemented through the configuration in which the pattern image is formed on the intermediate transfer belt 15 which is the image holding member and the tone density is read by the optical sensor 14b. However, a configuration in which the pattern image is printed on an image holding member such as a general sheet of paper which is not subjected to specific processing, or an OHP sheet which is a transparent resin sheet, and in the same manner, the optical sensor 14b reads the tone density may also be employed.

While certain embodiments have been described these embodiments have been presented by way of example only, and are not intended to limit the scope of the inventions. Indeed, the novel apparatus and methods described herein may be embodied in a variety of other forms: furthermore various omissions, substitutions and changes in the form of the apparatus and methods described herein may be made without departing from the spirit of the inventions. The accompanying claims and there equivalents are intended to cover such forms of modifications as would fall within the scope and spirit of the invention.

What is claimed is:

1. An image forming apparatus comprising:
an image holding member;
a plurality of image forming units which include at least a developer of a first color and a developer of a second color and forms a predetermined pattern image on the image holding member using the developers of the first and second colors;
an image density detection unit which detects an image density of the pattern image formed on the image holding member;
an image density comparison unit which compares the density of the pattern image detected by the image density detection unit to a target density;
a control unit which changes image forming conditions used by the plurality of image forming units on the basis of the comparison result of the image density comparison unit;
a developer residual amount acquisition unit which acquires a residual amount of the developer of the second color; and
an image stabilization kind determination unit which switches control of an image to image stabilization control of forming the pattern image to be formed on the image holding member using only the developer of the first color if the residual amount of the developer of the second color acquired by the developer residual amount acquisition unit is below a threshold value defined in advance.

2. The apparatus according to claim 1, wherein, if the residual amount of the developer of the second color acquired by the developer residual amount acquisition unit is below the threshold value defined in advance for any of the colors, the image stabilization kind determination unit performs switching of the control of an image so that the pattern image to be formed on the image holding member is formed using only the developer of the first color.

3. The apparatus according to claim 2, wherein the image forming units form the pattern image to have a plurality of tone densities.

4. The apparatus according to claim 2, further comprising:
an image formation processing unit which forms a print image of the developers of the first and second colors on the image holding member;
a recording unit which records image formation counts for each print image of the developers of the first and second colors formed by the image formation processing unit and an image formation count upper limit which is an execution determination reference of image stabilization control; and
an image stabilization execution determination unit which compares the image formation counts of the print image of the developer of the second color recorded on the recording unit to the image formation count upper limit recorded thereon, and determines whether or not the pattern image needs to be formed by the plurality of image forming units.

5. The apparatus according to claim 2, wherein the image density detection unit receives reflected light of light illuminated on the pattern image on the image holding member by an LED light source via an optical sensor, and calculates a density of the pattern image from the reflectance.

6. The apparatus according to claim 2,
wherein the control unit includes a memory which stores an upper limit curve and a lower limit curve for determining whether or not a tone characteristic generated using a plurality of pattern image densities calculated by the image density detection unit is in a range between an upper limit tone characteristic and a lower limit tone characteristic, and
the control unit performs an interpolation calculation using the pattern image densities calculated by the image density detection unit and the upper and lower limit curves stored in the memory and calculates the tone characteristic.

7. An apparatus comprising:
an image holding member;
a plurality of image forming units which include a developer of color black and a color developer of at least one color, and form a predetermined pattern image on the image holding member using the developer of the color black and the color developer;
an image density detection unit which detects an image density of the pattern image formed on the image holding member;
an image density comparison unit which compares the density of the pattern image detected by the image density detection unit to a target density;
a control unit which changes image forming conditions used by the plurality of image forming units on the basis of the comparison results of the image density comparison unit;
a developer residual amount acquisition unit which acquires a residual amount of the color developer of at least one color; and
an image stabilization kind determination unit which switches control of an image to image stabilization control of forming the pattern image to be formed on the image holding member using only the developer of the color black if the residual amount of the color developer acquired by the developer residual amount acquisition unit is below a threshold value defined in advance.

8. The apparatus according to claim 7, wherein, if the residual amount of the color developer acquired by the developer residual amount acquisition unit is below the threshold value defined in advance for any one of colors, the image stabilization kind determination unit performs switching of the control of an image so that the pattern image to be formed on the image holding member is formed using only the developer of the color black.

9. The apparatus according to claim 8, wherein the image forming units form the pattern image to have a plurality of tone densities.

10. The apparatus according to claim 8, further comprising:
an image formation processing unit which forms a print image of the developer of the color black and the color developer on the image holding member;
a recording unit which records image formation counts for each print image of the developer of the color black and the color developer formed by the image formation processing unit and an image formation count upper limit which is an execution determination reference of image stabilization control; and
an image stabilization execution determination unit which compares the image formation counts of the print image of the color developer recorded on the recording unit to the image formation count upper limit recorded thereon, and determines whether or not the pattern image needs to be formed by the plurality of image forming units.

11. The apparatus according to claim 8, wherein the image density detection unit receives reflected light of light illuminated on the pattern image on the image holding member by an LED light source via an optical sensor, and calculates a density of the pattern image from the reflectance.

12. The apparatus according to claim 8,
wherein the control unit includes a memory which stores an upper limit curve and a lower limit curve for determining whether or not a tone characteristic generated by using a plurality of pattern image densities calculated by the image density detection unit is in a range between an upper limit tone characteristic and a lower limit tone characteristic, and
the control unit performs an interpolation calculation using the pattern image densities calculated by the image density detection unit and the upper and lower limit curves stored in the memory and calculates the tone characteristic.

13. An image stabilization control method used in an image forming apparatus, comprising:
forming a predetermined pattern image on an image holding member using a developer of a first color and a developer of a second color;
detecting an image density of the pattern image formed on the image holding member;
comparing the detected density of the pattern image to a target density;
changing image forming conditions of the pattern image on the basis of the comparison result;
acquiring a residual amount of the developer of the second color; and
if the acquired residual amount of the developer of the second color is below a threshold value defined in advance, switching control of an image to image stabilization control of forming the pattern image to be formed on the image holding member using only the developer of the first color.

14. The method according to claim 13, wherein, if the acquired residual amount of the developer of the second color is below the threshold value defined in advance of any one of colors, switching of the control of an image is performed so that the pattern image to be formed on the image holding member is formed using only the developer of the first color.

15. The method according to claim 14, wherein the pattern image is formed to have a plurality of tone densities during execution of the image stabilization control.

16. The method according to claim 14,
wherein image formation counts of an image formed by an image forming apparatus using the developer of the second color and an image formation count upper limit which is an execution determination reference of image stabilization control are recorded on a recording unit, and
the image formation counts of the image of the developer of the second color recorded on the recording unit is compared to the image formation count upper limit recorded thereon, and whether or not the pattern image needs to be formed is determined.

17. An image stabilization control method used in an image forming apparatus, comprising:
forming a predetermined pattern image on an image holding member using a developer of color black and a color developer of at least one color;
detecting an image density of the pattern image formed on the image holding member;
comparing the detected density of the pattern image to a target density;
changing image forming conditions used by a plurality of image forming units on the basis of the comparison result;
acquiring a residual amount of the color developer; and
if the acquired residual amount of the color developer is below a threshold value defined in advance, switching control of an image to image stabilization control of forming the pattern image to be formed on the image holding member using only the developer of the color black.

18. The method according to claim 17, wherein, if the acquired residual amount of the color developer is below the threshold value defined in advance of any one of colors, switching of the control of an image is performed so that the pattern image to be formed on the image holding member is formed using only the developer of the color black.

19. The method according to claim 18, wherein the pattern image is formed to have a plurality of tone densities during execution of the image stabilization control.

20. The method according to claim 18,
wherein image formation counts of an image formed by an image forming apparatus using the color developer and an image formation count upper limit which is an execution determination reference of image stabilization control are recorded on a recording unit, and
the image formation counts of the color developer recorded on the recording unit is compared to the image formation count upper limit recorded thereon, and whether or not the pattern image needs to be formed is determined.
